(19) United States
(12) Patent Application Publication
(10) Pub. No.: US 2024/0178636 A1
(43) Pub. Date: May 30, 2024

(54) LIGHT-EMITTING DEVICE AND LASER SOURCE

(71) Applicant: HISENSE LASER DISPLAY CO., LTD., Shandong (CN)

(72) Inventors: Xin ZHANG, Shandong (CN); Youliang TIAN, Shandong (CN); Zinan ZHOU, Shandong (CN)

(21) Appl. No.: 18/319,790

(22) Filed: May 18, 2023

Related U.S. Application Data
(63) Continuation of application No. PCT/CN2021/130886, filed on Nov. 16, 2021.

(30) Foreign Application Priority Data
Feb. 18, 2021 (CN) 202110190280.7

(51) Int. Cl. H01S 5/22; H01S 5/02253; H01S 5/02255; H01S 5/40

(52) U.S. Cl. CPC H01S 5/2202; H01S 5/4031; H01S 5/02253; H01S 5/02255

(57) ABSTRACT

A light-emitting device and a laser are provided. The light-emitting device includes a first electrode, a light-emitting layer, an insulating layer and a second electrode which are sequentially arranged in a first direction; the light-emitting layer comprises a light-emitting portion and a non-light-emitting portion, an end of the light-emitting portion in the first direction is in contact with the second electrode through a via hole in the insulating layer, another end of the light-emitting portion in the first direction is in contact with the first electrode, and the non-light-emitting portion is covered by the insulating layer; and a surface of the non-light-emitting portion covered by the insulating layer is provided with a groove, the groove extends along a boundary between the light-emitting portion and the non-light-emitting portion, and the groove is used to block movement of carriers in the light-emitting layer from the light-emitting portion to the non-light-emitting portion.

### CROSS-REFERENCE TO RELATED APPLICATION

The present application is a continuation application of International Application No. PCT/CN2021/130886, filed on Nov. 16, 2021, which claims priority to Chinese Patent Application No. 202110190280.7, filed on Feb. 18, 2021 and entitled “LIGHT-EMITTING CHIP AND LASER”, the disclosure of both of which is herein incorporated by reference in their entirety.

### TECHNICAL FIELD

The present application relates to the field of photoelectric technologies, and in particular, relates to a light-emitting device and a laser source.

### BACKGROUND OF THE INVENTION

With the development of photoelectric technologies, laser sources are more and more widely used, and requirements for the luminous effect of the laser sources become higher and higher. At present, a laser source is usually provided with a plurality of light-emitting chips to improve the output power of the laser source. However, in related arts, the efficiency of current injection of the light-emitting chip is low, and the current density of the light-emitting region of the active layer is low, which lead to poor luminous effect of the light-emitting chip, thereby affecting the luminous efficiency and the output power of the laser source.

### SUMMARY OF THE INVENTION

In some embodiments, a light-emitting device is provided. The light-emitting device includes: a first electrode, a light-emitting layer, an insulating layer and a second electrode which are sequentially arranged in a first direction; wherein the light-emitting layer includes a light-emitting portion and a non-light-emitting portion, an end of the light-emitting portion in the first direction is in contact with the second electrode through a via hole in the insulating layer, another end of the light-emitting portion in the first direction is in contact with the first electrode, and the non-light-emitting portion is covered by the insulating layer; and a surface of the non-light-emitting portion covered by the insulating layer is provided with a groove, the groove extends along a boundary between the light-emitting portion and the non-light-emitting portion, and the groove is used to block movement of carriers in the light-emitting layer from the light-emitting portion to the non-light-emitting portion.

In some embodiments of the present application, a laser source is provided. The laser source includes: a plurality of the above light-emitting devices and a housing, wherein the plurality of light-emitting devices is arranged in an array in the housing.

### BRIEF DESCRIPTION OF DRAWINGS

FIG. 1 is a schematic structural diagram of a light-emitting chip in related arts;

FIG. 2 is a schematic diagram of transmission of a current in a light-emitting chip in related arts;

FIG. 3 is a schematic structural diagram of a light-emitting chip according to embodiments of the present application;

FIG. 4 is a schematic diagram of transmission of a current in a light-emitting chip according to embodiments of the present application;

FIG. 5 is a schematic structural diagram of another light-emitting chip according to embodiments of the present application;

FIG. 6 is a flowchart of a method for manufacturing a light-emitting chip according to embodiments of the present application;

FIG. 7 is a partially schematic structural diagram of a light-emitting chip according to embodiments of the present application;

FIG. 8 is a partially schematic structural diagram of another light-emitting chip according to embodiments of the present application;

FIG. 9 is a partially schematic structural diagram of yet another light-emitting chip according to embodiments of the present application;

FIG. 10 is a partially schematic structural diagram of still another light-emitting chip according to embodiments of the present application;

FIG. 11 is a partially schematic structural diagram of a light-emitting chip according to another embodiment of the present application;

FIG. 12 is a partially schematic structural diagram of another light-emitting chip according to another embodiment of the present application;

FIG. 13 is a schematic structural diagram of still yet another light-emitting chip according to embodiments of the present application;

FIG. 14 is a schematic structural diagram of still yet another light-emitting chip according to embodiments of the present application;

FIG. 15 is a schematic structural diagram of a laser source according to embodiments of the present application; and

FIG. 16 is a schematic structural diagram of another laser source according to embodiments of the present application.

### DETAILED DESCRIPTION OF THE INVENTION

To make the objectives, technical solutions, and advantages of the present application clearer, the embodiments of the present application are further described in detail hereinafter with reference to the accompanying drawings.

With the development of photoelectric technologies, laser sources with high power are more and more widely used. For example, a laser source can be used as a light source in a projection apparatus. The laser source includes a plurality of light-emitting devices, which may be light-emitting chips for example (or, light-emitting elements such as diodes, an integrated circuit board, a panel containing an array of light-emitting elements, etc.), and each light-emitting chip emits a laser light under excitation of a current, such that the laser source achieves luminescence. The luminous effect of the laser source is determined based on the luminous effect of the light-emitting chips, and thus requirements for the luminous effect and operation stability of the light-emitting chip are high.

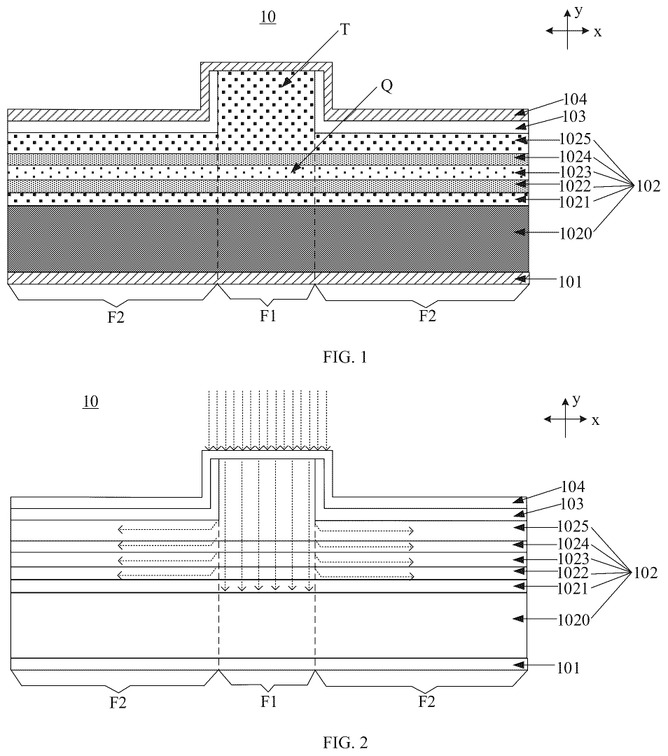

FIG. 1 is a schematic structural diagram of a light-emitting chip in related arts. As shown in FIG. 1, the light-emitting chip 10 includes: a first electrode 101, a substrate 1020, a first confinement layer 1021, a first waveguide layer 1022, an active layer 1023, a second waveguide layer 1024, a second confinement layer 1025, an insulating layer 103, and a second electrode 104 that are sequentially arranged in a first direction (for example, the y direction in the drawing). The structure of the substrate 1020, the first confinement layer 1021, the first waveguide layer 1022, the active layer 1023, the second waveguide layer 1024, the second confinement layer 1025 are referred to as a light-emitting layer 102. In embodiments, the film layers on the substrate are an epitaxial layer. The first electrode 101 and the second electrode 104 are respectively connected to a negative electrode and the positive electrode of a power supply, such that the first electrode 101 and the second electrode 104 supply a voltage to the light-emitting layer 102. For example, the first electrode 101 is connected to the negative electrode of the power supply, and the second electrode 104 is connected to the positive electrode of the power supply, such that the second electrode 104 injects the current to the light-emitting layer to excite the light-emitting layer to emit the laser light.

It should be noted that the first confinement layer 1021 and the second confinement layer 1025 are two different semiconductor layers. For example, the first confinement layer 1021 is an N-type semiconductor layer, and the second confinement layer 1025 is a P-type semiconductor layer. Holes in the N-type semiconductor layer and electrons in the P-type semiconductor layer are injected to the active layer 1023, population inversion is formed in the active layer 1023, and charge carriers, such as the electrons and the holes are recombined in the active layer 1023 to generate photons. A resonant cavity is formed, and the photons are oscillated and amplified in the resonant cavity. It is necessary to form a stable oscillation of the photons in the resonant cavity to ensure that the active layer consecutively and stably emits the laser light, and gains in the active layer are large enough to compensate for optical losses caused by the resonant cavity and losses caused by outputting the laser light from a cavity surface of the resonant cavity and increase an optical field in the resonant cavity. As the injection of the current to the light-emitting layer can improve the degree of the population inversion in the active layer, and the greater the degree of the population inversion, the greater the gains of the active layer, a strong enough current is required to be injected to the light-emitting layer. The current needs to meet a threshold condition, such that light with a stable wavelength is oscillated and amplified in the resonant cavity, eventually forms the laser light, and are consecutively output. The active layer 1023 confines movement of the charge carriers, and the first waveguide layer 1022 and the second waveguide layer 1024 confine transmission of the laser light emitted from the active layer 1023, such that the laser light is merely emitted from the active layer 1023.

The above light-emitting chip is a ridge light-emitting chip. The second confinement layer 1025 in the light-emitting chip 10 is in a ridge shape, that is, the side of the second confinement layer 1025 away from the substrate 1020 is provided with a strip protrusion T. The insulating layer 103 covers the region of the second confinement layer 1025 other than the surface of the strip protrusion T away from the substrate 1020, the second electrode 104 covers the insulating layer 103 and the second confinement layer 1025, and only the surface of the strip protrusion T away from the substrate 1020 in the second confinement layer 1025 is in contact with the second electrode 104. As such, the second electrode 104 injects the current to the light-emitting layer 102 through the surface of the strip protrusion T away from the substrate 1020, and the current can be vertically injected to a region Q covered by an orthogonal projection of the strip protrusion T in the active layer 1023, such that the region Q in the active layer 1023 emits the laser light. The region Q is an actual light-emitting region of the light-emitting chip.

A portion of the region of the light-emitting layer 102 in contact with the second electrode 104 is referred to as a light-emitting portion F1 of the light-emitting layer 102 hereinafter. The light-emitting portion F1 is the region covered by the strip protrusion T in the light-emitting layer 102, an orthogonal projection of the light-emitting portion F1 on the first electrode 101 overlaps with an orthogonal projection of the strip protrusion T on the first electrode 101, and the orthogonal projection of the light-emitting portion F1 on the first electrode 101 overlaps with an orthogonal projection of the light-emitting region Q in the active layer on the first electrode. The injection of the current to the light-emitting layer 102 by the second electrode 104 is the injection of the current to the light-emitting portion F1 of the light-emitting layer 102 by the second electrode 104. For example, the current is injected to the active layer (that is, the above light-emitting region Q) in the light-emitting portion F1 through the second confinement layer 1025 and the second waveguide layer 1024 in the light-emitting portion F1, such that the light-emitting portion is excited to emit the laser light (that is, the light-emitting region Q is excited to emit the laser light). The light-emitting portion F1 is in a strip shape, and is at the central region of the light-emitting layer. In embodiments, the width of the strip protrusion ranges from 30 μm to 40 μm, and thus the width of the light-emitting portion ranges from 30 μm to 40 μm. It should be noted that the light-emitting portion in the light-emitting layer is determined based on the contact region of the light-emitting layer and the second electrode. In the case that the contact region of the light-emitting layer and the second electrode is other region or in other shape, the position and the shape of the light-emitting portion change accordingly.

A portion of the light-emitting layer 102 other than the light-emitting portion F1 is referred to as a non-light-emitting portion F2 hereinafter. For example, the light-emitting layer 102 includes the light-emitting portion F1 and two non-light-emitting portions F2 respectively on two sides of the light-emitting portion F1 in a second direction (for example, the x direction). The second direction is perpendicular to the first direction. The second direction is the width direction of the light-emitting portion, and the two non-light-emitting portions are respectively on two sides in the width direction of the light-emitting portion. In embodiments, the light-emitting layer 102 includes a light-emitting portion and a non-light-emitting portion on the side of the light-emitting portion, and in this case, the light-emitting layer merely includes one light-emitting portion and one non-light-emitting portion. In embodiments, the light-emitting layer 102 includes a light-emitting portion and non-light-emitting portions on three sides of the light-emitting portion, and in this case, the light-emitting portion in the light-emitting layer is half-surrounded by the non-light-emitting portions.

In embodiments, a conductive layer (not shown in the drawing) is between the strip protrusion of the second confinement layer 1025 and the second electrode 104. For example, the conductive layer is an indium tin oxide (ITO) layer or a palladium/platinum/gold layer. The palladium/platinum/gold layer refers to an alloy of the palladium, platinum, and gold. The first electrode 101 may be a titanium/platinum/gold layer, the second electrode 104 may be a gold/nickel layer, and the insulating layer may be silicon dioxide. In the light-emitting layer 102, the material of the substrate 1020 may be gallium nitride, the material of the first confinement layer 1021 may be N-type doped aluminum gallium nitrogen, the material of the first waveguide layer 1022 may be N-type doped indium gallium nitrogen (n-InGaN), the material of the active layer 1023 may be in an indium gallium nitrogen (InGaN) multi-quantum well (MQW) structure, the material of the second waveguide layer 1024 may be un-doped indium gallium nitrogen (InGaN), and the material of the second confinement layer may include a P-type doped aluminum gallium nitrogen (p-AlGaN) electron-blocking layer (EBL) and a P-type doped aluminum gallium nitrogen (p-AlGaN)/gallium nitride (GaN) strain layer (SL), that is, the material for preparing the strain layer includes at least one of the p-AlGaN and gallium nitride (GaN). It should be noted that the materials of the film layers in the light-emitting chip can be replaced by other materials meeting the requirements of the film layers, which are not limited in the present application.

FIG. 2 is a schematic diagram of transmission of a current in a light-emitting chip in related arts. FIG. 2 shows the transmission of the current in the light-emitting chip shown in FIG. 1, and dotted lines with arrows in FIG. 2 are indicative of the current. The film layers in the light-emitting layer are all conductive, and the current is diffused from a region to other region of a film layer after the region of the film layer is injected to the current. As shown in FIG. 2, in the process of the injection of the current to the light-emitting layer 102, the current is vertically transmitted in the light-emitting portion F1 and is laterally diffused towards two sides of the light-emitting portion, such that the current density eventually arrived to the light-emitting region Q in the active layer 1023 is reduced, the charge carriers in the light-emitting region Q are diffused to two sides and lost, and an efficiency of charge carrier injection of the light-emitting region Q is reduced.

A lateral distribution of the current injected to the light-emitting chip in the light-emitting chip has adverse effects on characteristics of the light-emitting chip (for example, the threshold current, the wide of a lateral mode, the stability of the lateral mode, and the like), and the lateral mode of the light-emitting chip is represented by facula of the laser light emitted by the light-emitting chip. For example, for such light-emitting chip, the larger threshold current is required to excite the light-emitting region to emit the laser light, the larger current is required to be input to the light-emitting chip from external power supply, and the power consumption of the light-emitting chip is larger. As a distribution range of the current injected to the light-emitting chip is large, the width of the facula formed by the laser light emitted by the light-emitting chip is large, and the collimation of the laser light emitted by the light-emitting chip is low. As it is difficult to determine the current diffusion effect qualitatively, it is difficult to keep the facula of the laser light formed by the light-emitting chip being consistent, and the stability of the lateral mode of the light-emitting chip is poor. In addition, the large current injection may cause a high thermal load, and the current diffused beyond the light-emitting portion is dissipated in the form of heat, and such heat damages the life and reliability of the light-emitting chip. For the light-emitting chip in the laser source with high power, the threshold current increases more obviously, and the lateral diffusion of current has a better effect on the luminous effect and working stability of the light-emitting chip.

A light-emitting chip is provided in the embodiments of the present application, which can improve problems of low injection efficiency, stability, and poor reliability of the light-emitting chip.

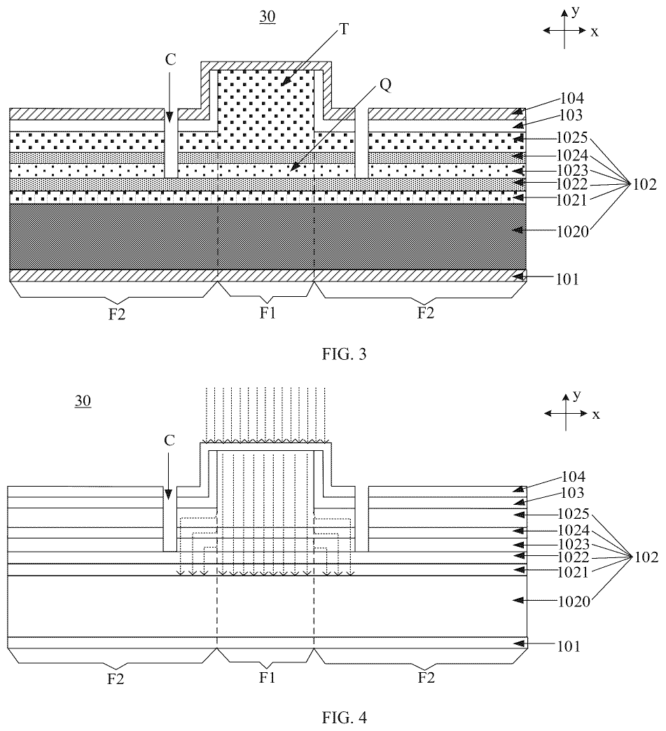

FIG. 3 is a schematic structural diagram of a light-emitting chip according to embodiments of the present application. As shown in FIG. 3, the light-emitting chip 30 includes: a first electrode 101, a light-emitting layer 102, an insulating layer 103, and a second electrode 104 that are sequentially laminated in a first direction ((for example, the y direction in FIG. 3). The light-emitting layer 102 at least includes a first confinement layer 1021, an active layer 1023, and a second confinement layer 1025 that are sequentially laminated in the first direction. The light-emitting layer 102 is divided into a light-emitting portion F1 and a non-light-emitting portion F2 which is on at least one side of the light-emitting portion F1. A groove C is provided at the side of the non-light-emitting portion F2 proximal to the second electrode 104, and the groove C is on an end of the non-light-emitting portion F2 proximal to the light-emitting portion F1. An extending direction of the groove C is intersected with an arrangement direction of the light-emitting portion F1 and the non-light-emitting portion F2, and the depth direction of the groove C is parallel with the first direction. For example, the arrangement direction of the light-emitting portion F1 and the non-light-emitting portion F2 is parallel with the second direction, and the extending direction of the groove C is intersected with the second direction. In FIG. 3, the extending direction of the groove C is the direction perpendicular to the surface of the paper. It should be noted that other structure of the light-emitting chip 30 other than the groove may be referred to related description of the light-emitting chip 10 in FIG. 1, which will not be repeated herein.

In the embodiments of the present application, the groove C is used to isolate the structures in the light-emitting layer 102 on both sides of the groove C, such that the structures on both sides of the groove C are no longer conductive. As such, the current injected to the light-emitting portion F1 on one side of the groove C is only transmitted in the structure on the side of the groove C, and will not diffuse to the structure of the non-light-emitting portion on the other side of the groove C. Thus, the diffusion range of the current is limited, and the current is injected to the light-emitting portion more intensively. Furthermore, the efficiency of current injection of the light-emitting portion can be improved, the current density and photoelectric conversion efficiency of the light-emitting portion can be improved, the threshold current and the wide of the lateral mode of the light-emitting chip can be reduced, and the lateral mode stability, the life, and the working reliability of the light-emitting chip can be improved.

For example, FIG. 4 is a schematic diagram of transmission of a current in a light-emitting chip according to embodiments of the present application. FIG. 4 shows the transmission of the current in the light-emitting chip shown in FIG. 3, and dotted lines with arrows in FIG. 4 is used to indicate the current. As shown in FIG. 4, during the process of the injection of the current to the light-emitting layer 102, most of the current is vertically transmitted in the light-emitting portion F1, and only a small amount of the current is laterally diffused towards two sides of the light-emitting portion F1, which is blocked by the groove C when diffused to the groove C and is re-transmitted towards the substrate 1020 vertically. Comparing with the case of the current transmission in FIG. 2, the current is confined between two grooves C in FIG. 4. Thus, in the same injection condition of the external current, the current density eventually arrived to the light-emitting region Q in the active layer 1023 and the efficiency of charge carrier injection of the light-emitting region Q in the light-emitting chip 30 in the embodiments of the present application are higher.

In summary, in the light-emitting chip in the embodiments of the present application, the groove is provided in the side of the non-light-emitting portion in the light-emitting layer proximal to the second electrode, and the groove is on the end of the non-light-emitting portion proximal to the light-emitting portion. The extending direction of the groove is intersected with the arrangement direction of the light-emitting portion and the non-light-emitting portion, and the depth direction of the groove is parallel with the first direction. As such, after the second electrode injects the current to the light-emitting portion, the groove blocks the diffusion of the current toward the side of the groove in the non-light-emitting portion away from the light-emitting portion. Thus, the current is injected to the light-emitting portion more intensively, the current density of the light-emitting portion is higher, and the luminous effect of the light-emitting chip is better.

In a specific example, the distance between the groove C and the light-emitting portion F1 ranges from 10 μm to 20 μm. That is, the distance between the groove C and the strip protrusion T in the second direction ranges from 10 m to 20 μm. For example, the distance between the groove C and the light-emitting portion F1 is 10 m, 15 m, or the like. In embodiments, the width of the groove C ranges from 10 μm to 20 μm. That is, the size of the groove C in the second direction ranges from 10 μm to 20 μm. For example, the width of the groove C is 10 μm, 15 μm, or the like. In a specific example, the depth of the groove ranges from 20 μm to 50 am. That is, the size of the groove C in the first direction ranges from 20 μm to 50 μm. For example, the depth of the groove C is 20 μm, 25 μm, or the like.

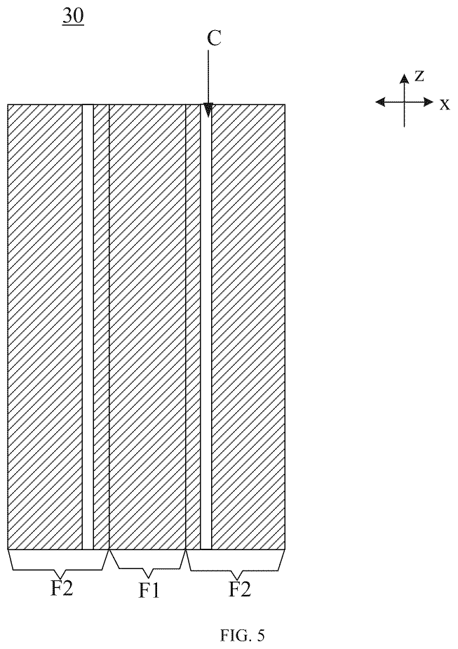

FIG. 5 is a schematic structural diagram of another light-emitting chip according to embodiments of the present application. FIG. 5 is a top view of the light-emitting chip shown in FIG. 3. In the embodiments of the present application, an end, proximal to the second electrode 104, of an end of each non-light-emitting portion F2 in the light-emitting layer proximal to the light-emitting portion F1 is provided with the groove C. As shown in FIG. 3 and FIG. 5, two non-light-emitting portions F2 on two sides of the light-emitting portion F1 in the x direction are provided with the groove C. In embodiments, in the case that the light-emitting layer merely includes one non-light-emitting portion on the side of the light-emitting portion, the light-emitting layer merely includes one groove. In the case that the light-emitting layer includes three non-light-emitting portions on three sides of the light-emitting portion, the light-emitting layer includes three grooves. In embodiments, the three grooves are connected, which is not limited in the embodiments of the present application.

In the embodiments of the present application, the extending direction of the groove C is perpendicular to the arrangement direction of the light-emitting portion F1 and the non-light-emitting portion F2 of the groove C. For example, in conjunction with FIG. 3 and FIG. 5, the light-emitting portion F1 and the non-light-emitting portion F2 are arranged in the second direction (that is, the x direction), and the grooves C are arranged in a third direction. The third direction is the direction perpendicular to the surface of the paper, that is, the z direction in FIG. 5. The third direction is perpendicular to the second direction, and is perpendicular to the first direction (that is, the y direction).

In embodiments, the non-light-emitting portion F2 is in a strip shape. As shown in FIG. 5, the groove C is a through groove penetrating the non-light-emitting portion F2 in the length direction (that is, the z direction) of the non-light-emitting portion F2. The groove C separates the non-light-emitting portion F2 therein to two portions. For example, the length of the cavity of the light-emitting chip is 1200 μm, and the width of the light-emitting chip is 150 μm. The whole light-emitting chip is in a rectangle shape, the length of the cavity of the light-emitting chip is the length of the rectangle, and the width of the light-emitting chip is the width of the rectangle. The light-emitting portion F1 and the non-light-emitting portion F2 are arranged in the width direction of the light-emitting chip, and the length direction of the non-light-emitting portion F2 is parallel with the direction of the length of the cavity of the light-emitting chip. The groove C penetrates the non-light-emitting portion F2 in the length direction of the non-light-emitting portion F2, and thus the length of the groove C is equal to the length of the cavity of the light-emitting chip. For example, the length of the groove C in the extending direction thereof is 1200 μm.

In embodiments, the groove does not penetrate the non-light-emitting portion in the z direction. In this case, the groove merely blocks the transmission of the current on a part of positions in the non-light-emitting portion. For example, one end of the groove is connected to an outer side of the non-light-emitting portion in the z direction, and the other end of the groove is not connected the outer side of the non-light-emitting portion. For example, both ends of the groove are not connected the outer side of the non-light-emitting portion, and the groove is a blind groove.

Referring to FIG. 3, the groove C penetrates the second confinement layer 1025, the second waveguide layer 1024, and the active layer 1023 in the first direction. As the active layer emits the lase under the action of the injected current in the light-emitting layer, and the luminous effect of the light-emitting layer is ensured to be good by intensively transmitting the current to the active layer, the depth of the groove is deposed to just penetrate the active layer. In embodiments, the groove C merely penetrates the second confinement layer 1025 in the first direction, or the groove C merely penetrates the second confinement layer 1025 and the second waveguide layer 1024 in the first direction. In this case, the diffusion of the current is blocked to some extent, such that the efficiency of the current injection of the light-emitting portion is improved.

In embodiments, referring to FIG. 3, the insulating layer 103 in the light-emitting chip 30 is provided with a through hole, the through hole in the insulating layer 103 communicates with the groove in the non-light-emitting portion, and the through hole in the insulating layer 103 may be a part of the groove in the non-light-emitting portion.

In summary, in the light-emitting chip in the embodiments of the present application, the groove is provided in the side of the non-light-emitting portion in the light-emitting layer proximal to the second electrode, and the groove is on the end of the non-light-emitting portion proximal to the light-emitting portion. The extending direction of the groove is intersected with the arrangement direction of the light-emitting portion and the non-light-emitting portion, and the depth direction of the groove is parallel with the first direction. As such, after the second electrode injects the current to the light-emitting portion, the groove blocks the diffusion of the current toward the side of the groove in the non-light-emitting portion away from the light-emitting portion. Thus, the current is injected to the light-emitting portion more intensively, the current density of the light-emitting portion is higher, and the luminous effect of the light-emitting chip is better.

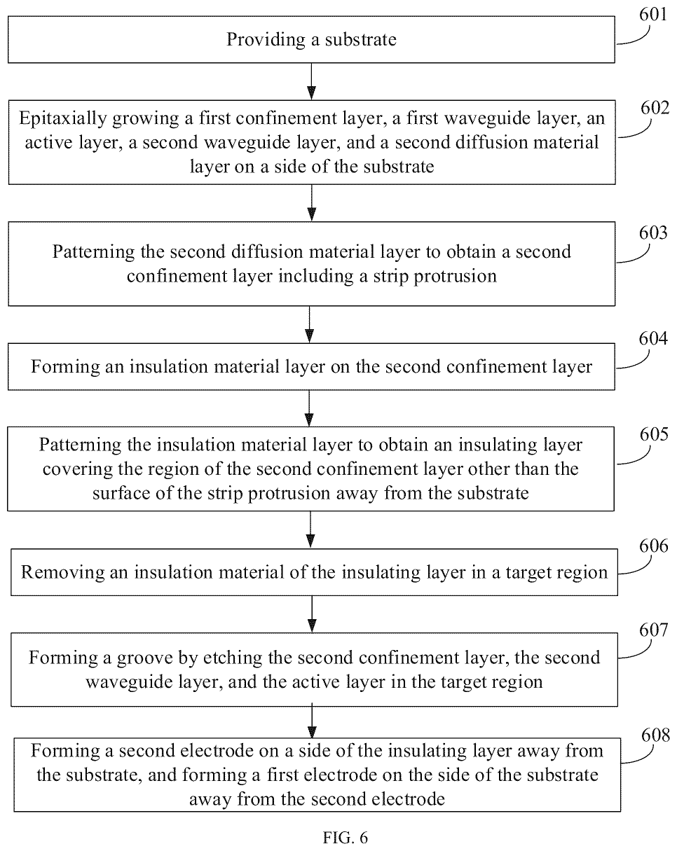

FIG. 6 is a flowchart of a method for manufacturing a light-emitting chip according to embodiments of the present application, and the method is applicable to the light-emitting chip in FIG. 3 or FIG. 5. For example, the groove in the light-emitting chip in the embodiments of the present application is formed by a deep etching process. As shown in FIG. 6, the method includes the following processes.

In S601, a substrate is provided.

Illustratively, the material of the substrate is gallium nitride (GaN). In embodiments, the material of the substrate may be silicon, gallium antimonide (GaSb), gallium arsenide (GaAs), indium phosphide (InP), indium arsenide (InAs), indium antimonide (InSb), and the like. In embodiments, the size of the substrate is the same as the size of the eventually formed light-emitting chip. For example, the substrate is a rectangle with a length of 1200 μm and a width of 150 μm.

In S602, a first confinement layer, a first waveguide layer, an active layer, a second waveguide layer, and a second diffusion material layer are sequentially and epitaxially grown on a side of the substrate.

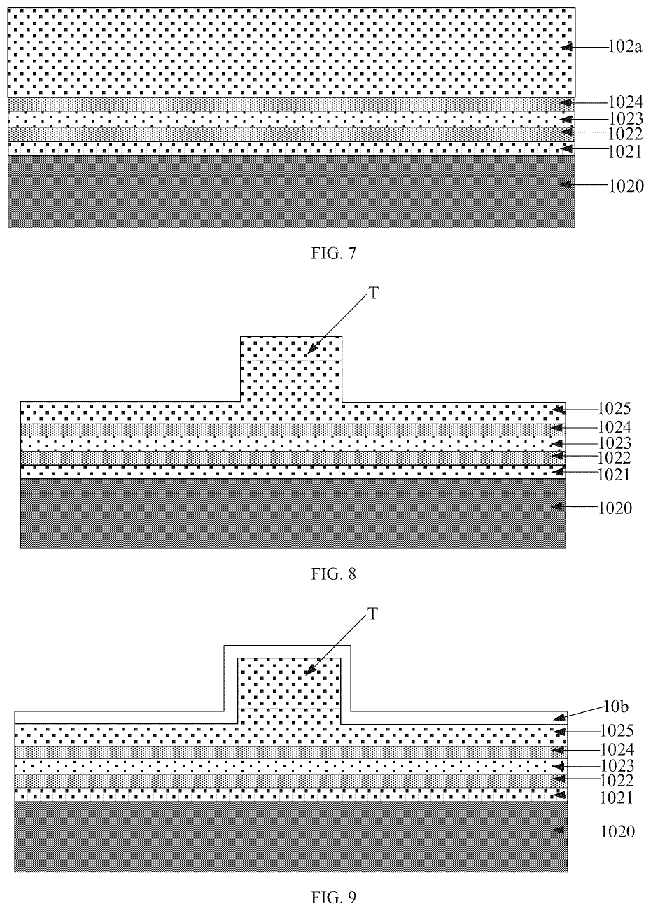

In embodiments, as the center wavelength of the laser light emitted by the light-emitting chip is associated with the material of the film layer in the light-emitting chip, the center wavelength of the laser light emitted by the light-emitting chip is determined prior to manufacturing of the light-emitting chip, and then materials of the film layers in the light-emitting chip are determined based on the center wavelength. For example, materials of the first confinement layer, the first waveguide layer, the active layer, the second waveguide layer, and the second diffusion material layer are determined based on the center wavelength, and corresponding film layers are sequentially grown on the substrate by means of crystal growth based on the materials of the film layers. For example, FIG. 7 is a partially schematic structural diagram of a light-emitting chip according to embodiments of the present application. The first confinement layer 1021, the first waveguide layer 1022, the active layer 1023, the second waveguide layer 1024, and the second diffusion material layer 102a are sequentially and epitaxially grown on the side of the gallium nitride substrate to obtain the structure shown in FIG. 7.

It should be noted that the film layers epitaxially grown on the substrate are referred to as an epitaxial layer, and the materials of the film layers can be referred to as the above corresponding description for the film layers in FIG. 1, which are not repeated herein in the embodiments of the present application.

In S603, the second diffusion material layer is patterned to obtain a second confinement layer including a strip protrusion.

Illustratively, after the second diffusion material layer 102a is formed on the substrate, the epitaxial layer on the substrate is cleaned. Then, the second confinement layer 1025 including a strip protrusion T at the central region shown in FIG. 8 is obtained by performing one patterning process on the second diffusion material layer 102a (for example, performing a photolithography process on the second diffusion material layer). The patterning process for once includes photoresist coating, exposing, developing, etching, and photoresist removing. In embodiments, the width of the strip protrusion T is 40 μm. The first confinement layer, the first waveguide layer, the active layer, the second waveguide layer, and the second diffusion material layer form the light-emitting layer of the light-emitting chip.

In embodiments, a conduction material layer is formed on the second diffusion material layer upon S602, the conduction material layer and the second diffusion material layer are simultaneously patterned in S603 to obtain the second confinement layer including the strip protrusion and a conductive layer on the strip protrusion, and the following processes are performed. For example, the conductive layer is an indium tin oxide layer or a palladium/platinum/gold layer. For example, an indium tin oxide material layer or a palladium/platinum/gold layer is formed on the second diffusion material layer, and the conductive layer is formed by patterning the indium tin oxide material layer or a palladium/platinum/gold layer.

In S604, an insulation material layer is form on the second confinement layer.

For example, the insulation material is deposited on the second confinement layer 1025 by a plasma enhanced chemical vapor deposition (PECVD) to form the insulation material layer 10b. In this case, the structure shown in FIG. 9 is obtained. For example, the insulation material is silicon dioxide, and the thickness of the insulation material layer is 500 μm.

In S605, the insulation material layer is patterned to obtain an insulating layer covering the region of the second confinement layer other than the surface of the strip protrusion away from the substrate.

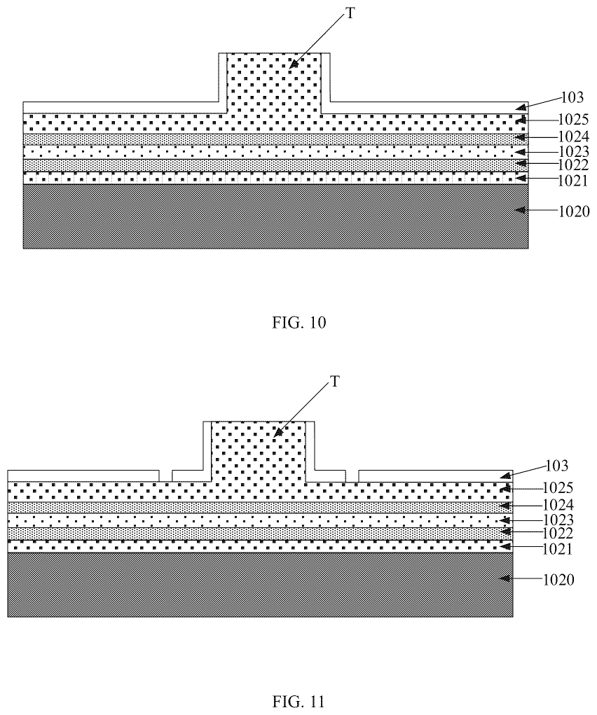

For example, the one patterning process is performed on the insulation material layer 10b, and the material of the insulation material layer 10b above the strip protrusion T is etched to obtain the structure shown in FIG. 10. In the structure, the insulating layer 103 merely covers the region of the second confinement layer 1025 other than the surface of the strip protrusion T away from the substrate 1020, and the surface of the strip protrusion T away from the substrate 1020 is exposed.

In embodiments of the present application, the structure shown in FIG. 10 is directly provided, and then subsequent processes for manufacturing the light-emitting chip are performed.

In S606, an insulation material of the insulating layer in a target region is removed.

The target region is a region in the insulating layer in which the groove is to be formed. For example, the target region M is a strip region with a width of 10 μm at a position with a distance of 10 μm from the strip protrusion in the second confinement layer 1025. For example, the insulation material in the target region M is corroded by wet etching, and thus the structure shown in FIG. 11 is obtained. Then, the remaining structure is cleaned by removing the photoresist.

In S607, a groove is formed by etching the second confinement layer, the second waveguide layer, and the active layer in the target region.

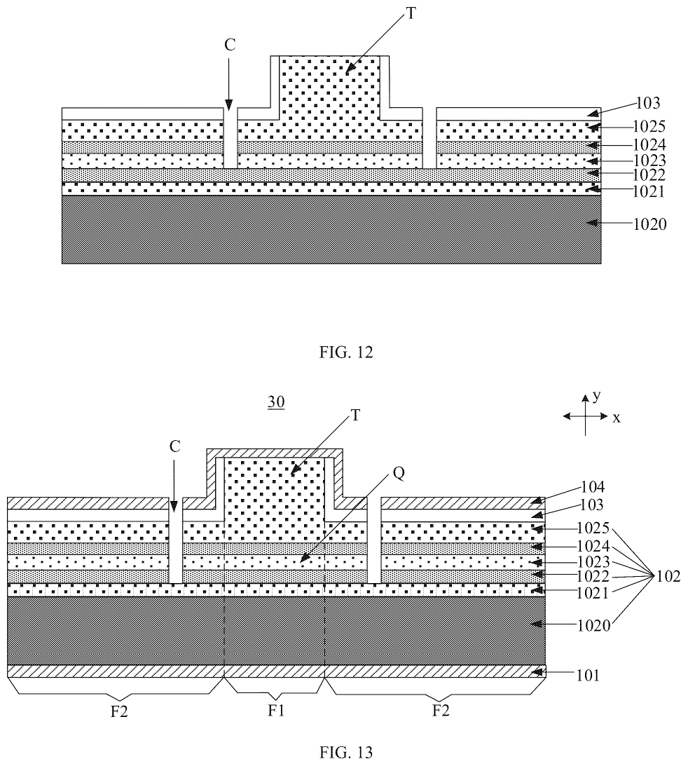

For example, the insulating layer 103 with the insulation material in the target region being removed is determined as a mask, and the second confinement layer 1025, the second waveguide layer 1024, and the active layer 1023 are etched by inductively coupled plasma (ICP) to form a groove penetrating the second confinement layer 1025, the second waveguide layer 1024, and the active layer 1023. In this case, the structure shown in FIG. 12 is obtained. In embodiments, the depth of the groove is controlled by controlling an etching time. For example, by reducing the etching time, the formed groove C merely penetrates the second confinement layer 1025 and the second waveguide layer 1024. Alternatively, by increasing the etching time, the formed groove C further penetrates the first waveguide layer 1022 and the first confinement layer 1021.

In S608, a second electrode is formed on the side of the insulating layer away from the substrate, and a first electrode is formed on the side of the substrate away from the second electrode.

For example, after the groove is formed, the first electrode is formed on the side of the substrate away from the second electrode and the second electrode is formed on the side of the insulating layer away from the substrate by magnetron sputtering. For example, the first electrode is a titanium/platinum/gold layer, and the second electrode is a gold/nickel layer. In this case, the light-emitting chip 30 shown in FIG. 3 is obtained.

In summary, in the light-emitting chip manufactured by the manufacturing method in the embodiments of the present application, the groove is provided in the side of the non-light-emitting portion in the light-emitting layer proximal to the second electrode. As such, after the second electrode injects the current to the light-emitting portion, the groove blocks the diffusion of the current toward the side of the groove in the non-light-emitting portion away from the light-emitting portion. Thus, the current is injected to the light-emitting portion more intensively, the current density of the light-emitting portion is higher, and the luminous effect of the light-emitting chip is better.

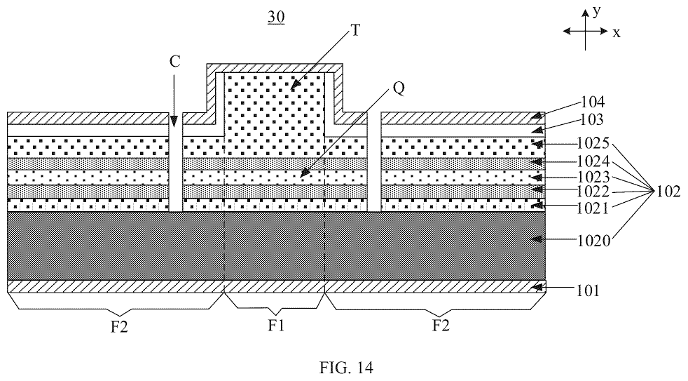

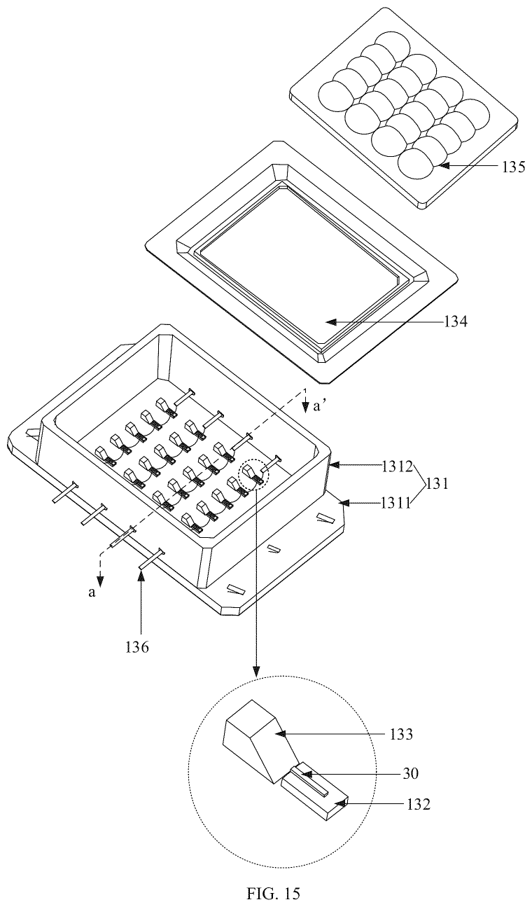

FIG. 13 is a schematic structural diagram of still yet another light-emitting chip according to embodiments of the present application. Referring to FIG. 13, in an example, the above groove C penetrating the second confinement layer 1025, the second waveguide layer 1024 and the active layer 1023 may further penetrates the first waveguide layer 1022. FIG. 14 is a schematic structural diagram of still yet another light-emitting chip according to embodiments of the present application. Referring to FIG. 14, in an example, the above groove C penetrating the second confinement layer 1025, the second waveguide layer 1024 and the active layer 1023 may further penetrates the first waveguide layer 1022 and the first confinement layer 1021 (in this case, the groove C penetrates the entire epitaxial layer on the substrate). Both of the above examples can be achieved, for example, by controlling the etching time in step 607 above. Based on the same principle, the groove C of the above two examples can also be set in such a way that the diffusion of current is blocked, thereby improving the efficiency of current injection in the light-emitting portion. In addition, considering that the etching rate at different locations may vary, the depth of the groove C at different locations of the light-emitting chip may vary (for example, at some locations the groove C does not penetrate the first limiting layer 1021, while at other locations the groove C penetrates the first limiting layer 1021). However, such differences do not affect the groove C to play a role in blocking the diffusion of current, so the implementation where the groove C penetrates different numbers of layers at different locations is also a possible implementation of the embodiment of the present application.

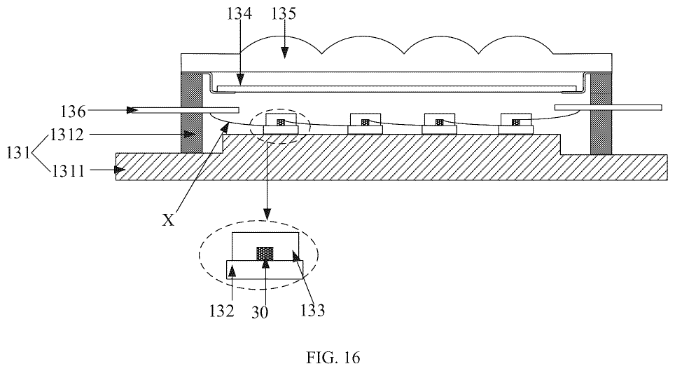

FIG. 15 is a schematic structural diagram of a laser source according to embodiments of the present application, and FIG. 16 is a schematic structural diagram of another laser source according to embodiments of the present application. FIG. 15 is a schematic diagram of a decomposition structure of the laser source, and FIG. 16 is a schematic diagram of a section a-a′ in FIG. 15. As shown in FIG. 15 and FIG. 16, the laser source further includes: a housing 131 and a plurality of light-emitting chips 30. The plurality of light-emitting chips 30 are arranged in the housing 131. The light-emitting chip is the light-emitting chip shown in FIG. 3 or FIG. 5. The laser source further includes a plurality of heat sinks 132, a plurality of reflective prisms 133, a transparent seal layer 134, a collimating lens set 135, and a plurality of conductive pins 136.

The housing 131 is provided with an opening, the housing 131 includes a base plate 1311 and a sidewall 1312, the base plate of the housing 131 is opposite to the housing, and the sidewall of the housing 131 defines the opening. The plurality of heat sinks 132 and the plurality of reflective prisms 133 are attached on the base plate, the transparent seal layer 134 and the collimating lens set 135 are sequentially fixed on the opening of the housing 131 in a direction away from the base plate, and the plurality of conductive pins 136 penetrate the sidewall of the housing 131 and is fixed on the sidewall. Each light-emitting chip 30 corresponds to one heat sink 132 and one reflective prism 133, the collimating lens set 135 includes a plurality of collimating lenses, and each collimating lens corresponds to one light-emitting chip 30. Each light-emitting chip 30 is attached on the side of the corresponding heat sink 132 away from the base plate of the housing 131, and a reflective surface of the reflective prism 133 corresponding to the light-emitting chip 30 is opposite to a light-exiting opening of the light-emitting chip 30.

Each row of light-emitting chips 30 are in parallel. Two light-emitting chips 30 in each row of light-emitting chips 30 on edges are respectively connected to two conductive pins 136 on the sidewall, and the two conductive pins 136 are respectively fixed on two opposite sides of the sidewall. For example, the two conductive pins 136 include a first conductive pin and a second conductive pin, a first electrode of one of the two light-emitting chips 30 is connected to an end of the first conductive pin in the housing via a wire X, and a second electrode of the other of the two light-emitting chips 30 is connected to an end of the second conductive pin in the housing 131 via a wire X. The end of the first conductive pin in the housing is connected to the positive electrode of an external power supply, and the end of the second conductive pin in the housing 131 is connected to the negative electrode of the external power supply. As such, the external power supply supplies a current to one row of the light-emitting chips 30 through the first conductive pin and the second conductive pin to excite the one row of the light-emitting chips 30 to emit the laser light. The laser light emitted by each light-emitting chip 30 may be directed to the reflective surface of the corresponding reflective prism 133, the laser light passes through the transparent seal layer 134 upon being reflected by the reflective prism 133 and then directed to the collimating lens in the collimating lens set 135 corresponding to the light-emitting chip 30, and then the laser light is transmitted upon being collimated by the collimating lens, such that luminous of the laser source is achieved.

In summary, in the light-emitting chip in the embodiments of the present application, the groove is provided in the side of the non-light-emitting portion in the light-emitting layer proximal to the second electrode, and the groove is on the end of the non-light-emitting portion proximal to the light-emitting portion. The extending direction of the groove is intersected with the arrangement direction of the light-emitting portion and the non-light-emitting portion, and the depth direction of the groove is parallel with the first direction. As such, after the second electrode injects the current to the light-emitting portion, the groove blocks the diffusion of the current toward the side of the groove in the non-light-emitting portion away from the light-emitting portion. Thus, the current is injected to the light-emitting portion more intensively, the current density of the light-emitting portion is larger, the luminous effect of the light-emitting chip is better, and thus the luminous effect of the laser source is better.

It should be noted that in the present application, the term “A/B layer” indicates that the material of a film layer includes at least one of A and B, the term “A/B/C layer” indicates that the material of a film layer includes at least one of A, B, and C, and so on. For example, in the case that A and B refer to metals, the term “A/B layer” indicates that the film layer is a film layer formed by an alloy including A and B. For example, a titanium/platinum/gold layer indicates that the film layer is a film layer formed by an alloy of titanium, platinum, and gold, and a gold/nickel layer indicates that the film layer is a film layer formed by an alloy of gold and nickel.

In the present application, the term “at least one of A and B” is merely an associated relationship of the associated objects, and indicates that there may be three relationships. For example, at least one of A and B may indicate that there are three cases where A exists separately, A and B exist simultaneously, and B exists separately. Similarly, the term “at least one of A, B, and C” indicates that there may be seven relationships where A exists separately, B exists separately, B exists separately, A and B exist simultaneously, A and C exist simultaneously, C and B exist simultaneously, and A, B, and C exist simultaneously. In the present application, the terms “first” and “second” are only used for the purpose of description and should not be construed as indicating or implying relative importance. Unless otherwise clearly defined, the expression “a plurality of” refers to two or more. The term “almost” refers that within an acceptable error range, those skilled in the art can solve the technical problem within an error range and basically achieve the technical effect. It should be noted that in the accompanying drawings, for clarity of the illustration, the dimension of the layers and regions may be scaled up. It should be understood that when an element or layer is described as being “on” another element or layer, the described element or layer may be directly located on other elements or layers, or an intermediate layer may exist. In the whole disclosure, like reference numerals indicate like elements.

In the embodiments of the present application, the method embodiments and the device embodiments can refer to each other, which are not limited in the embodiments of the present application. Described above are merely exemplary embodiments of the present application, and are not intended to limit the present application. Any modifications, equivalent replacements, improvements and the like made within the spirit and principles of the present application should be encompassed within the scope of protection of the present application.

What is claimed is:

1. A light-emitting device, comprising: a first electrode, a light-emitting layer, an insulating layer and a second electrode which are sequentially arranged in a first direction; wherein
the light-emitting layer comprises a light-emitting portion and a non-light-emitting portion, an end of the light-emitting portion in the first direction is in contact with the second electrode through a via hole in the insulating layer, another end of the light-emitting portion in the first direction is in contact with the first electrode, and the non-light-emitting portion is covered by the insulating layer; and
a surface of the non-light-emitting portion covered by the insulating layer is provided with a groove, the groove extends along a boundary between the light-emitting portion and the non-light-emitting portion, and the groove is used to block movement of carriers in the light-emitting layer from the light-emitting portion to the non-light-emitting portion.

2. The light-emitting device according to claim 1, wherein the light-emitting layer comprises a first confinement layer, an active layer and a second confinement layer which are sequentially arranged in the first direction, and the groove penetrates the second confinement layer and the active layer.

3. The light-emitting device according to claim 2, wherein the light-emitting layer further comprises a first waveguide layer and a second waveguide layer, the first waveguide layer is between the first confinement layer and the active layer, the second waveguide layer is between the active layer and the second confinement layer, and the groove further penetrates the second confinement layer.

4. The light-emitting device according to claim 3, wherein the groove further penetrates the first waveguide layer.

5. The light-emitting device according to claim 4, wherein the groove further penetrates the first confinement layer.

6. The light-emitting device according to claim 1, further comprising a substrate between the first electrode and the light-emitting layer, a bottom surface of the groove is provided by a surface of the substrate on a side of the substrate away from the first electrode.

7. The light-emitting device according to claim 1, wherein the light-emitting layer comprises two non-light-emitting portions respectively on two opposite sides of the light-emitting portion, a surface of each of the non-light-emitting portions covered by the insulating layer is provided with a groove, which extends along a boundary between the light-emitting portion and the non-light-emitting portion, and used to block movement of carriers in the light-emitting layer from the light-emitting portion to the non-light-emitting portion.

8. The light-emitting device according to claim 1, wherein the insulating layer is provided with a through hole, and the through hole is connected to the groove.

9. The light-emitting device according to claim 1, wherein a distance between the groove and the light-emitting portion ranges from 10 μm to 20 μm.

10. The light-emitting device according to claim 1, wherein a width of the groove ranges from m to 20 μm.

11. The light-emitting device according to claim 1, wherein a depth of the groove ranges from m to 50 μm.

12. A laser source comprising at least one light-emitting device according to claim 1.

13. The laser source according to claim 13, comprising: a plurality of light-emitting devices according to claim 1, and a housing, wherein the plurality of light-emitting devices is arranged in an array in the housing.

14. The laser source according to claim 12, wherein the light-emitting layer of each light-emitting device comprises a first confinement layer, an active layer and a second confinement layer which are sequentially arranged in the first direction, and the groove penetrates the second confinement layer and the active layer.

15. The laser source according to claim 14, wherein the light-emitting layer of each light-emitting device further comprises a first waveguide layer and a second waveguide layer, the first waveguide layer is between the first confinement layer and the active layer, the second waveguide layer is between the active layer and the second confinement layer, and the groove further penetrates the second confinement layer.

16. The laser source according to claim 15, wherein the groove further penetrates the first waveguide layer.

17. The laser source according to claim 16, wherein the groove further penetrates the first confinement layer.

18. The laser source according to claim 12, wherein each of the at least one light-emitting device further comprises a substrate between the first electrode and the light-emitting layer, wherein a bottom surface of the groove is provided by a surface of the substrate on a side of the substrate away from the first electrode.

19. The laser source according to claim 12, wherein the light-emitting layer of each light-emitting device comprises two non-light-emitting portions respectively on two opposite sides of the light-emitting portion, a surface of each of the non-light-emitting portions covered by the insulating layer is provided with a groove, which extends along a boundary between the light-emitting portion and the non-light-emitting portion, and used to block movement of carriers in the light-emitting layer from the light-emitting portion to the non-light-emitting portion.

20. The laser source according to claim 12, wherein the insulating layer of each light-emitting device is provided with a through hole, and the through hole is connected to the groove.
